(19) United States
(12) Patent Application Publication
(10) Pub. No.: US 2025/0228051 A1
(43) Pub. Date: Jul. 10, 2025

(54) DISPLAY PANEL AND DISPLAY DEVICE

(71) Applicants: BOE MLED TECHNOLOGY CO., LTD., Beijing (CN); BOE TECHNOLOGY GROUP CO., LTD., Beijing (CN)

(72) Inventors: Zeng Liang, Beijing (CN); Yicheng Lin, Beijing (CN); Linfeng Li, Beijing (CN); Qiuhua Meng, Beijing (CN); Huanxin Yue, Beijing (CN)

(21) Appl. No.: 18/700,254

(22) PCT Filed: Mar. 31, 2023
(86) PCT No.: PCT/CN2023/085553

§ 371 Date: Apr. 10, 2024

(51) Int. Cl. H10H 29/49

(52) U.S. Cl. CPC H10H 29/49

(57) ABSTRACT

A display panel includes: a base including a first surface and a second surface on opposite sides of the base, respectively; a pixel array provided on the first surface of the base, including a plurality of pixel units arranged in an array along a first direction and a second direction, at least one pixel unit includes a plurality of light-emitting diodes, and the light-emitting diode includes a first electrode and a second electrode; and a signal processing chip provided on the first surface of the base, where the signal processing chip includes at least one signal channel terminal, and the signal channel terminal is electrically connected to the first electrode of the light-emitting diode. The signal processing chip further includes a wireless signal receiving terminal, which is configured to receive at least one signal wirelessly. The at least one signal includes a data signal.

### CROSS-REFERENCE TO RELATED APPLICATION

This application is a Section 371 National Stage Application of International Application No. PCT/CN2023/085553, filed Mar. 31, 2023, which is incorporated herein by reference in its entirety.

### TECHNICAL FIELD

The present disclosure relates to a field of display technology, in particular to a display panel and a display device.

### BACKGROUND

Light-emitting diode (LED) technology has been developed for nearly thirty years, and its application range is constantly expanding. For example, LEDs may be used in the display field as a backlight for a display device or as an LED display screen. With the development of technology, mini light-emitting diodes (Mini LED) gradually become a research hotspot in the field of display technology. For example, Mini LEDs in combination with the driving technology of thin film transistors (TFT) have advantages in capacity of production, costs and downward compatibility with micro light-emitting diodes (Micro LED), and gradually become a mainstream research direction in the field of display technology. With the improvement of display resolution and the widespread use of large-sized displays, the wiring in display panels based on sub-millimeter light-emitting diodes or miniature light-emitting diodes becomes increasingly complex, posing challenges to the design of the display panels.

The above information disclosed in this section is only for understanding the background of the technical concept of the present disclosure. Therefore, the above information may include information that does not constitute the prior art.

### SUMMARY

In order to solve at least one aspect of the above problems, embodiments of the present disclosure provide a display panel and a display device.

In an aspect, a display panel is provided, including: a base comprising a first surface and a second surface located on opposite sides of the base respectively; a pixel array provided on the first surface of the base, wherein the pixel array comprises a plurality of pixel units arranged in an array along a first direction and a second direction, at least one pixel unit comprises a plurality of light-emitting diodes, and the light-emitting diode comprises a first electrode and a second electrode; and a signal processing chip provided on the first surface of the base, wherein the signal processing chip comprises at least one signal channel terminal electrically connected to the first electrode of the light-emitting diode, wherein the signal processing chip further comprises one or more wireless signal receiving terminals, the wireless signal receiving terminal is configured to receive at least one signal wirelessly, and the at least one signal comprises a data signal.

According to some exemplary embodiments, the at least one signal further comprises a power supply voltage signal.

According to some exemplary embodiments, the signal processing chip is a pixel driver chip for driving a pixel unit.

According to some exemplary embodiments, cach signal processing chip is configured to drive one pixel unit, and the signal processing chip comprises a plurality of signal channel terminals electrically connected to first electrodes of a plurality of light-emitting diodes of the one pixel unit in a one-to-one correspondence.

According to some exemplary embodiments, the display panel further includes a ground line provided on the first surface of the base, the ground line being configured to transmit a ground signal. The signal processing chip further comprises a ground signal terminal, the ground signal terminal being electrically connected to the ground line through wired connection.

According to some exemplary embodiments, in the signal processing chip for driving a same pixel unit, an orthographic projection of the ground signal terminal on the base and orthographic projections of the plurality of signal channel terminals on the base are arranged in a column along the second direction.

According to some exemplary embodiments, the display panel further includes a circuit board and a ground signal lead, wherein the circuit board is provided on the second surface of the base, at least a part of the ground signal lead is provided on a first side surface of the base, and the first side surface is a side surface of the base between the first surface and the second surface; and the circuit board is electrically connected to the ground line through the ground signal lead.

According to some exemplary embodiments, the display panel further includes a plurality of power supply signal lines provided on the first surface of the base, wherein second electrodes of the plurality of light-emitting diodes of the one pixel unit are electrically connected to the plurality of power supply signal lines, respectively.

According to some exemplary embodiments, the display panel further includes a power supply signal lead, wherein at least a part of the power supply signal lead is provided on the first side surface of the base; and the circuit board is electrically connected to the power supply signal line through the power supply signal lead.

According to some exemplary embodiments, the ground line comprises a first ground sub-line extending in the first direction and a second ground sub-line extending in the second direction, and the first ground sub-line and the second ground sub-line intersect with each other to form a mesh.

According to some exemplary embodiments, each of an orthographic projection of the ground signal terminal on the base and orthographic projections of the plurality of signal channel terminals on the base at least partially overlaps with an orthographic projection of the second ground sub-line on the base, respectively.

According to some exemplary embodiments, cach signal processing chip is configured to drive more than one pixel unit, the signal processing chip comprises a plurality of signal terminal groups, and cach signal terminal group comprises more than one signal channel terminal; and the more than one signal channel terminal of each signal terminal group of the signal processing chip are electrically connected to first electrodes of a plurality of light-emitting diodes of one pixel unit in a one-to-one correspondence.

According to some exemplary embodiments, the more than one pixel unit driven by a same signal processing chip comprises pixel units located in two rows adjacent to each other, and/or, pixel units located in two columns adjacent to each other.

According to some exemplary embodiments, the display panel further includes a ground line provided on the first surface of the base, wherein the ground line is configured to transmit a ground signal; and cach signal terminal group further comprises a ground signal terminal, and a plurality of ground signal terminals of the plurality of signal terminal groups of a same signal processing chip are electrically connected to a plurality of ground lines through wired connection.

According to some exemplary embodiments, the display panel further includes a plurality of signal processing chips arranged in at least one chip column parallel to a pixel column in the pixel array, and the chip column is between two pixel columns adjacent to each other.

According to some exemplary embodiments, for a same signal processing chip, orthographic projections of ground signal terminals and signal channel terminals in at least two signal terminal groups for driving pixel units in a same column on the base are arranged in a column along the second direction.

According to some exemplary embodiments, for a same signal processing chip, orthographic projections of ground signal terminals and signal channel terminals in at least two signal terminal groups for driving pixel units in different columns on the base are arranged in different columns.

According to some exemplary embodiments, the signal processing chip is a general control chip; and the display panel further comprises one or more pixel driver chips for driving the pixel units on the first surface of the base, and the general control chip is in wired connection with the pixel driver chip to perform signal transmission with the pixel driver chip.

According to some exemplary embodiments, the display panel includes a plurality of general control chips, wherein each general control chip is in wired connection with a plurality of pixel driver chips to perform signal transmission with the plurality of pixel driver chips.

In another aspect, a display device is provided, including the display panel as described above.

### BRIEF DESCRIPTION OF THE DRAWINGS

Through the following descriptions of the present disclosure with reference to the accompanying drawings, other objectives and advantages of the present disclosure will become more apparent, and may contribute to a comprehensive understanding of the present disclosure.

FIG. 1 is a diagram of a system architecture of a Mini/Micro LED display panel according to an embodiment of the present disclosure;

FIG. 2 is a side view of the display panel shown in FIG. 1, which schematically shows wires on a side surface of the display panel;

FIG. 3 is a schematic top view of a front surface of a display panel according to some exemplary embodiments of the present disclosure;

FIG. 4 is a diagram showing a principle of driving a pixel of the display panel

shown in FIG. 3;

FIG. 5 is a schematic diagram of a structure of a pixel of the display panel shown in FIG. 3;

FIG. 6 is a schematic top view of a back surface of a display panel according to some exemplary embodiments of the present disclosure;

FIG. 7 is a schematic top view of a front surface of a display panel according to some other exemplary embodiments of the present disclosure;

FIG. 8 is a diagram showing a principle of driving a pixel of the display panel shown in FIG. 7;

FIG. 9 is a schematic diagram of a structure of a pixel of the display panel shown in FIG. 7;

FIG. 10 is a diagram showing a principle of driving a pixel of a display panel according to some other exemplary embodiments of the present disclosure; and

FIG. 11 is a schematic top view of a back surface of the display panel shown in FIG. 10.

It will be noted that for the sake of clarity, in the accompanying drawings used to describe the embodiments of the present disclosure, dimensions of layers, structures or regions may be enlarged or reduced, that is, these drawings are not drawn according to actual scales.

### DETAILED DESCRIPTION OF EMBODIMENTS

In the following description, for explanation, many specific details are set forth to provide comprehensive understanding for various exemplary embodiments. However, it is obvious that the various exemplary embodiments may be implemented without these specific details or with one or more equivalent arrangements. In other cases, well-known structures and devices are shown in block diagram form to avoid causing unnecessary ambiguity of the various exemplary embodiments. In addition, the various exemplary embodiments may be different, but are not required to be exclusive. For example, without departing from the inventive concept, the specific shapes, configurations and features of the exemplary embodiments may be used or implemented in another exemplary embodiment.

In the drawings, for the sake of clarity and/or description, a size and a relative size of an element may be enlarged. In this way, sizes and relative sizes of the various elements are not required to be limited to the sizes and relative sizes shown in the drawings. When the exemplary embodiments may be implemented differently, the specific process sequence may be performed differently from the described sequence. For example, two continuously described processes may be substantially performed simultaneously or in a sequence opposite to the described sequence. In addition, the same reference numeral represents the same element.

When an element is described as being “on”, “connected to”, or “coupled to” another element, the element may be directly on, directly connected to, or directly coupled to the other element, or intermediate elements may be existed. However, when an element is described as being “directly on”, “directly connected to”, or “directly coupled to” another element, there is no intermediate element existed. Other terms and/or expressions used to describe a relationship between elements will be interpreted in a similar fashion, e.g., “between” versus “directly between”, “adjacent” versus “directly adjacent”, or “on” versus “directly on” etc. Furthermore, the term “connected” may refer to a physical connection, an electrical connection, a communication connection, and/or a fluid connection. In addition, an X axis, a Y axis and a Z axis are not limited to a three axes of a rectangular coordinate system, and may be interpreted in a broader sense. For example, the X, Y, and Z axes may be perpendicular to each other, or may represent different directions that are not perpendicular to each other. For the purposes of the present disclosure, “at least one of X, Y, and Z” and “at least one selected from the group formed by X, Y, and Z” may be interpreted as only X, only Y, only Z, or any combination of two or more of X, Y and Z such as XYZ, XYY, YZ and ZZ. As used herein, the term “and/or” includes any combination and all combinations of one or more of the listed associated items.

It will be understood that, although the terms first, second, etc. may be used herein to describe different elements, these elements should not be limited by these terms. These terms are only used to distinguish one component from another component. For example, without departing from the scope of the example embodiment, a first element may be referred to as a second element. Similarly, the second element may be referred to as the first element.

Herein, inorganic light-emitting diodes refer to light-emitting elements made from inorganic materials. LED represents an inorganic light-emitting element that is different from OLED. Specifically, the inorganic light-emitting element may include a Mini light-emitting diode (Mini LED) and a Micro light-emitting diode (Micro LED). The Mini light-emitting diode (i.e. Mini LED) refers to a small light-emitting diode with a die size between that of a Micro LED and that of a traditional LED. Generally, the die size of the Mini LED may be between 50 um and 400 um.

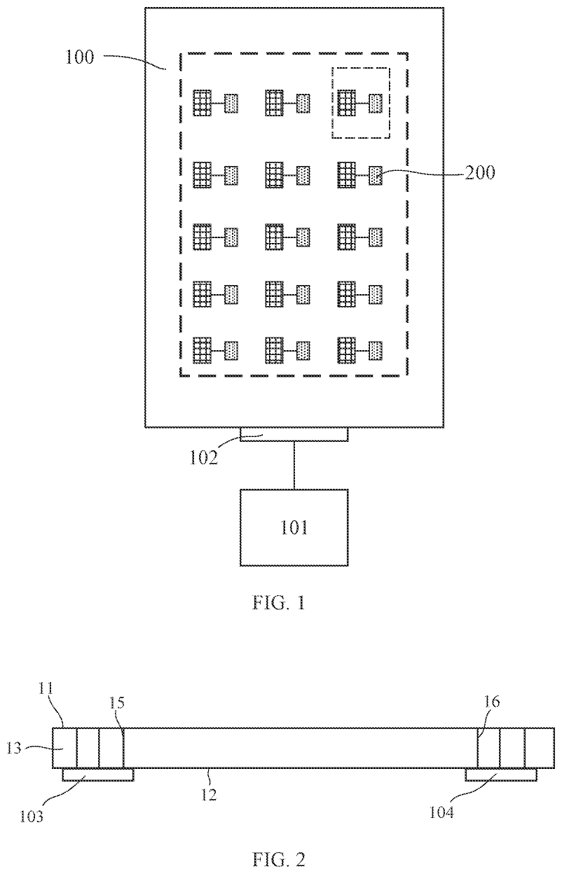

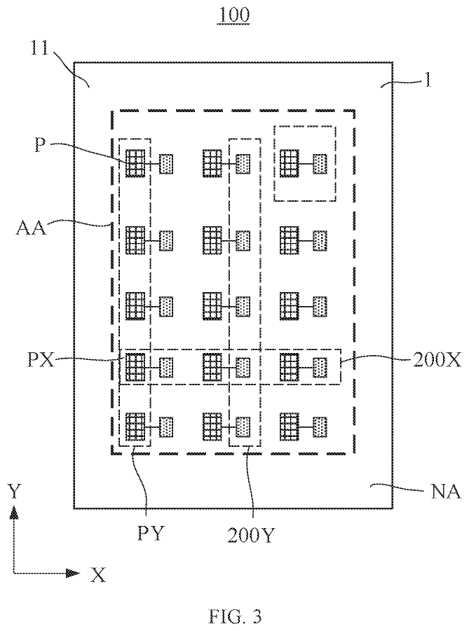

FIG. 1 is a diagram of a system architecture of a Mini/Micro LED display panel according to an embodiment of the present disclosure. FIG. 2 is a side view of the display panel shown in FIG. 1, which schematically shows wires of a side surface of the display panel. With reference to FIG. 1 and FIG. 2, in the Mini/Micro LED display panel 100 driven by means of active addressing, signals are transmitted from a sending card 101 (such as a system on chip, SoC) to a receiving card terminal of an adapter board (such as a HUB board) 102 through an HDMI interface or a network port, and then the signals are transmitted to pixel driver chips 200 by the receiving card terminal through leads, so as to control the display of each pixel unit.

The pixel driver chips 200 need to receive their respective ground signals (GND), respective power supply voltage signals (VCC) and data signals, respectively. With reference to FIG. 1 and FIG. 2, a circuit board is provided on a back surface of the display panel 100, for example, the display panel 100 is provided with two or more power supply circuit boards 103 and one or more data signal circuit boards 104. The power supply circuit board 103 may provide ground signals (i.e. GND) and power supply voltage signals (i.e. VCC), and the data signal circuit board 104 may be used to provide data signals. The pixel units and the pixel driver chips 200 are provided on a front surface of the display panel 100.

It will be noted that herein, the expression “front surface” represents a surface of the display panel facing the user during the normal use, and the expression “back surface” represents a surface of the display panel away from the user during the normal use. For case of description, the “front surface” may be referred to as a “first surface”, and the “back surface” may be referred to as a “second surface”.

In the related art, the circuit board provided on the back surface of the display panel 100 is electrically connected to the respective pixel driver chips 200 provided on the front surface of the display panel 100 through a plurality of wires. That is, the circuit board on the back surface of the display panel 100 is electrically connected to the pixel driver chips 200 on the front surface of the display panel 100 through wired connection, so as to transmit the ground signals (i.e. GND), the power supply voltage signals (i.e. VCC) and the data signals to the pixel driver chips 200. Two ends of the wire are respectively connected to the circuit board and the pixel driver chip by using a bonding process, and at least part of the wire is on a side surface of the display panel 100. With the improvement of the display resolution and the widespread use of large-sized displays, the number of wires required for transmitting the ground signals (GND), power supply voltage signals (VCC) and data signals is increased. Correspondingly, a density of bonding points and a density of wires on the side surface are increased, resulting in more complex bonding and side surface wiring processes.

In order to solve at least one aspect of the above problems, embodiments of the present disclosure provides a display panel. The display panel includes: a base including a first surface and a second surface located on opposite sides of the base respectively; a pixel array provided on the first surface of the base, where the pixel array includes a plurality of pixel units arranged in an array along a first direction and a second direction, at least one pixel unit includes a plurality of light-emitting diodes, and the light-emitting diode includes a first electrode and a second electrode; and a signal processing chip provided on the first surface of the base, where the signal processing chip includes at least one signal channel terminal, and the signal channel terminal is electrically connected to the first electrode of the light-emitting diode. The signal processing chip further includes a wireless signal receiving terminal configured to receive at least one signal wirelessly, and the at least one signal includes a data signal. In the embodiments of the present disclosure, a wireless transmission function is integrated to the chip located on the first surface (i.e. the front surface) of the display panel, and at least the data signal is received wirelessly through the wireless signal receiving terminal of the chip. In this way, the bonding points and the wires on the side surface of the display panel may be reduced, so as to contribute to a reduction of the process difficulty and an improvement of the product yield.

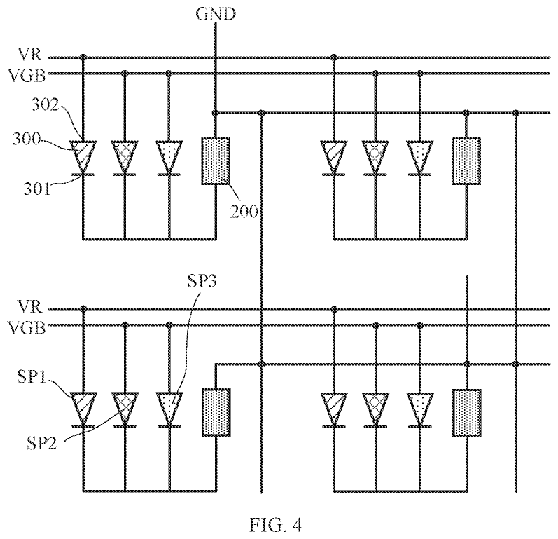

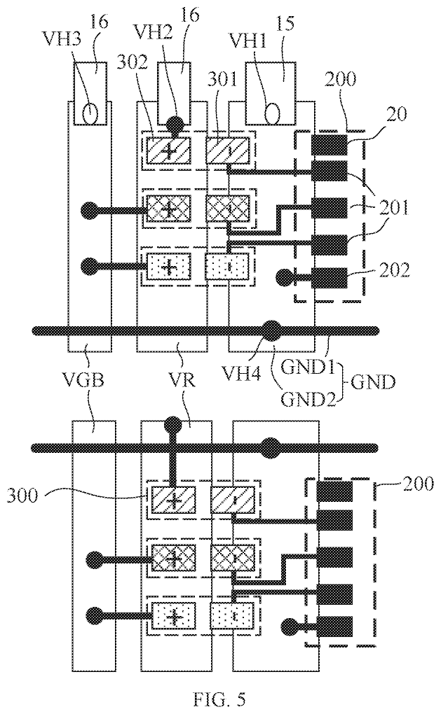

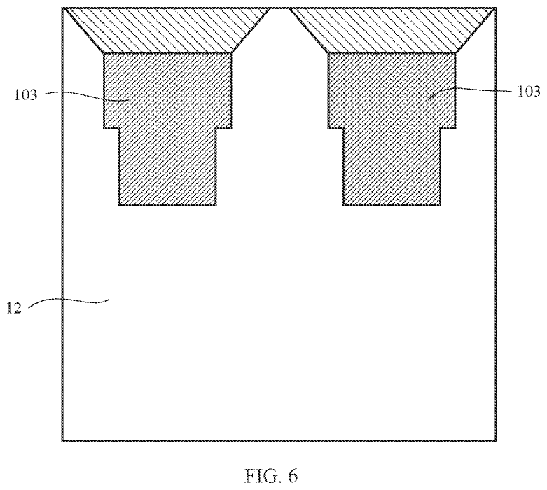

FIG. 3 is a schematic top view of a front surface of a display panel according to some exemplary embodiments of the present disclosure. FIG. 4 is a diagram showing a principle of driving a pixel of the display panel shown in FIG. 3. FIG. 5 is a schematic diagram of a structure of a pixel of the display panel shown in FIG. 3. FIG. 6 is a schematic top view of a back surface of a display panel according to some exemplary embodiments of the present disclosure.

It will be noted that in the present disclosure, the embodiments of the present disclosure will be specifically described by taking the Mini/Micro LED display panel 100 adopting an active addressing driving method as an example.

With reference to FIG. 1 to FIG. 6, the display panel 100 may include a base 1. The base 1 includes a first surface 11 and a second surface 12, and the first surface 11 and the second surface 12 are located on opposite sides of the base 1, respectively. For example, the first surface 11 may be a front surface of the base 1, and the second surface 12 may be a back surface of the base 1.

The base 1 may be a rigid base or a flexible base, a material of which includes glass, quartz, PMMA (polymethyl methacrylate), plastic, etc. However, the embodiments of the present disclosure do not impose special limitations on this.

The display panel 100 includes a pixel array provided on the first surface 11 of the base 1, and the pixel array includes a plurality of pixel units P arranged in an array along a first direction X and a second direction Y. At least one pixel unit P includes a plurality of light-emitting diodes 300, and a light-emitting diode 300 includes a first electrode 301 and a second electrode 302.

With reference to FIG. 3, the pixel array is provided on the base 1. The display panel may include a display area AA and a peripheral area NA surrounding the display area AA. The pixel array may be provided in the display area AA of the display panel. As shown in FIG. 3, the pixel array may include a plurality of pixel rows PX and a plurality of pixel columns PY, the pixel row PX may extend along the first direction X, and the pixel column PY may extend along the second direction Y.

It will be noted that the first direction X may intersect with the second direction Y, for example, the first direction X may be perpendicular to the second direction Y. However, the embodiments of the present disclosure do not impose special limitations on this. The number of the pixel rows PX may be even or odd. The number of the pixel rows PY may be even or odd. The embodiments of the present disclosure do not impose special limitations on the number of pixel rows and the number of pixel columns.

The display panel 100 may further include a signal processing chip provided on the first surface 11 of the base 1. The signal processing chip includes at least one signal channel terminal, and the signal channel terminal is electrically connected to the first electrode 301 of the light-emitting diode.

In the embodiments of the present disclosure, the signal processing chip further includes a wireless signal receiving terminal, the wireless signal receiving terminal may receive at least one signal wirelessly, and the at least one signal includes a data signal.

In some exemplary embodiments, the signal processing chip is a pixel driver chip 200. That is, the pixel driver chip 200 includes a wireless signal receiving terminal 20. The wireless signal receiving terminal 20 is configured to receive at least one signal wirelessly. For example, the at least one signal includes a data signal.

In the embodiments of the present disclosure, a wireless transmission function is integrated to each pixel driver chip, and at least the data signal is received wirelessly through the wireless signal receiving terminal of the pixel driver chip. In this way, the bonding points and the wires on the side surface may be reduced, which may contribute to the reduction of the process difficulty and the improvement of the product yield. Advantageously, the inventors found through research that in the related art, a respective wire is provided for each pixel column to transmit a data signal from the back surface of the display panel to the front surface of the display panel, and with an increase of the display resolution and the widespread use of large-sized displays, the number of these wires is increased significantly. In the embodiments of the present disclosure, the wireless transmission method is used to transmit at least the data signal, so that the number of such wires may be significantly reduced, thereby significantly reducing the number of bonding points of data signal lines and the number of the wires on the side surface.

With continued reference to FIG. 3, the pixel row PX may include a plurality of pixel units P. The pixel column PY may include a plurality of pixel units P. As shown in FIG. 5, the pixel unit P may include a plurality of sub-pixels. Colors of light emitted from the plurality of sub-pixels may be different or may be the same. Specifically, the plurality of sub-pixels may include a first sub-pixel SP1, a second sub-pixel SP2, and a third sub-pixel SP3. The first sub-pixel SP1 may be a red sub-pixel, or it may be a blue sub-pixel, but the present disclosure is not limited to this, and it may be a green sub-pixel. The second sub-pixel SP2 may be a red sub-pixel, or it may be a blue sub-pixel, but the present disclosure is not limited to this, and it may be a green sub-pixel. The third sub-pixel SP3 may be a red sub-pixel, or it may be a blue sub-pixel, but the present disclosure is not limited to this, and it may be a green sub-pixel. Taking the colors of the light emitted from the plurality of sub-pixels being different as an example, the first sub-pixel SPI is a red sub-pixel used for emitting red light, the second sub-pixel SP2 is a green sub-pixel used for emitting green light, and the third sub-pixel SP3 is a blue sub-pixel used for emitting blue light. Each sub-pixel may include one or more light-emitting diodes 300. The light-emitting diode 300 may be a Mini LED. Alternatively, the light-emitting diode 300 may be a Micro LED, but the embodiments of the present disclosure are not limited to this. In the present disclosure, the sub-pixel including one light-emitting diode is taken as an example. For example, an orthographic projection of the light-emitting diode 300 on the base may be in a shape of a quadrilateral. The light-emitting diode is an independent component that may be provided on the base through surface mount technology or mass transfer technology. The light-emitting diode 300 includes a first electrode 301 and a second electrode 302. For example, the first electrode 301 is one of a positive electrode and a negative electrode of the light-emitting diode 300. The second electrode 302 is the other one of the positive electrode and the negative electrode of the light-emitting diode 300. For example, each of an orthographic projection of the first electrode 301 and an orthographic projection of the second electrode 302 on the base may be in a shape of a quadrilateral.

In the embodiments of the present disclosure, the pixel driver chips 200 with the wireless transmission function and the pixel units P are provided on a same side of the base 1, for example, both of them are provided on the first surface 11 of the base 1. The pixel driver chip 200 is connected to the pixel unit P. The pixel driver chip 200 may be connected to the plurality of sub-pixels in the pixel unit P. Specifically, a signal terminal of the pixel driver chip 200 may include a plurality of signal channel terminals 201.The plurality of signal channel terminals 201 of the pixel driver chip 200 are connected to the plurality of sub-pixels in the pixel unit P in a one-to-one correspondence. Taking the sub-pixel including the light-emitting diode as an example, the signal channel terminal 201 may be connected to the first electrode 301 of the light-emitting diode.

The display panel 100 further includes a plurality of power supply signal lines. The power supply signal line may be arranged parallel to the pixel column PY. The power supply signal line is connected to the pixel unit P, where the power supply signal line is connected to the sub-pixels in the pixel unit P. Specifically, the power supply signal line is connected to the second electrode 302 of the light-emitting diode of the sub-pixel. With reference to FIG. 5, the plurality of power supply signal lines may include a first power supply signal line VR and a second power supply signal line VGB. Red sub-pixels in pixel units P located in the same pixel column may be connected to the first power supply signal line VR, and the green sub-pixels and blue sub-pixels in the pixel units P are connected to the second power supply signal line VGB. That is, the green sub-pixels and the blue sub-pixels in the pixel units P located in the same pixel column share a same power supply signal line, contributing to the reduction of the number of the power supply signal lines.

It will be noted that in FIG. 5, two pixel units in different rows and their respective pixel driver chips are schematically shown, and the pixel unit on the upper side may be a pixel unit in a top row of the display panel, and the pixel unit on the lower side may be a pixel unit in a bottom row of the display panel.

In the embodiments of the present disclosure, the wireless signal receiving terminal 20 is configured to receive at least one signal wirelessly, and the at least one signal further includes a power supply voltage signal. That is to say, the power supply voltage signal and the data signal are both transmitted to the pixel driver chip 200 through wireless transmission. In this way, the data signal and the power supply voltage signal may be received wirelessly through the wireless signal receiving terminal of the pixel driver chip, so that the bonding points of the data signal lines and the power supply voltage signal lines and the wires on the side surface may be reduced, contributing to a further reduction of the process difficulty, thereby improving the product yield.

In the embodiments shown in FIG. 3 to FIG. 6, cach pixel driver chip 200 is used to drive one pixel unit P, that is, the pixel driver chips 200 corresponds to the pixel units P one by one.

In a case that each pixel unit P includes three sub-pixels, the pixel driver chip 200 includes three signal channel terminals 201, and the three signal channel terminals 201 are electrically connected to the first electrodes 301 of the plurality of light-emitting diodes of the pixel unit in a one-to-one correspondence.

The pixel driver chip 200 may further include a ground signal terminal 202. That is, one pixel driver chip 200 includes three signal channel terminals 201 and one ground signal terminal 202.

In the embodiments of the present disclosure, the number of signal terminals required for a single pixel driver chip 200 may be reduced, and thus contributing to a reduction of a size of a single pixel driver chip.

As shown in FIG. 5, for the pixel driver chip 200 for driving a same pixel unit P, an orthographic projection of the ground signal terminal 202 on the base 1 and orthographic projections of the plurality of signal channel terminals 201 on the base 1 are arranged in a column along the second direction Y. In this way, the size of a single pixel driver chip 200 in the first direction X may be reduced, which is beneficial to the reduction of a pitch (i.e. a periodical size) of repetitive units in the first direction X, thereby contributing to the realization of a high-resolution display panel.

It will be noted that the repetitive unit here may represent a combination of a pixel unit and a pixel driver chip corresponding to the pixel unit.

The display panel 100 further includes a ground line GND provided on the first surface 11 of the base. The ground line is used to transmit a ground signal. The ground signal terminal of the pixel driver chip 200 is electrically connected to the ground line GND through wired connection.

With reference to FIG. 6, a circuit board is provided on the back surface of the display panel 100 (i.c. the second surface 12). For example, two power supply circuit boards 103 are provided. The power supply circuit board 103 may provide the ground signal and the power supply signal.

With reference to FIG. 2, FIG. 5 and FIG. 6, the display panel 100 further includes a ground signal lead 15. At least a part of the ground signal lead 15 is provided on a first side surface 13 of the base 1. The first side surface 13 is a side surface of the base 1 between the first surface 11 and the second surface 12. Specifically, one end of the ground signal lead 15 is electrically connected to the power supply circuit board 103, and the other end of the ground signal lead 15 is electrically connected to the ground line GND. For example, the other end of the ground signal lead 15 is electrically connected to the ground line GND through a via hole VH1. A part of the ground signal lead 15 between the two ends of the ground signal lead 15 is provided on the first side surface 13 of the base 1.

The display panel 100 further includes a power supply signal lead 16. At least a part of the power supply signal lead 16 is provided on the first side surface 13 of the base. Specifically, a plurality of power supply signal leads 16 are provided. One end of a power supply signal lead 16 is electrically connected to the power supply circuit board 103, and the other end of the power supply signal lead 16 is electrically connected to the first power supply signal line VR. For example, the other end of the power supply signal lead 16 is electrically connected to the first power supply signal line VR through a via hole VH2. One end of another power supply signal lead 16 is electrically connected to the power supply circuit board 103, and the other end of this power supply signal lead 16 is electrically connected to the second power supply signal line VGB. For example, the other end of the power supply signal lead 16 is electrically connected to the second power supply signal line VGB through a via hole VH3.

In other words, in the embodiments of the present disclosure, the ground signal and the power supply signal are still transmitted to the chip and pixel units provided on the first surface 11 of the base 1 wirelessly.

It will be noted that in the embodiment illustrated in the figure, the first side surface 13 may be a side surface of the display panel on the upper side of the display panel, that is, the ground signal lead 15 and the power supply signal lead 16 are both bent from the upper side of the display panel to the front surface of the display panel. However, the embodiments of the present disclosure are not limited to this. The ground signal lead 15 and the power supply signal lead 16 may also be bent from other sides of the display panel to the front surface of the display panel, or the ground signal lead 15 and the power supply signal lead 16 may also be bent from different sides of the display panel to the front surface of the display panel.

With reference to FIG. 5, the ground line GND includes a first ground sub-line GND1 and a second ground sub-line GND2. The first ground sub-line GND1 extends in the first direction X, the second ground sub-line GND2 extends in the second direction Y, and the first ground sub-line GND1 and the second ground sub-line GND2 intersect with each other to form a mesh. For example, the first ground sub-line GND1 and the second ground sub-line GND2 may be electrically connected to each other through a via hole VH4.

Each of the orthographic projection of the ground signal terminal 202 of the pixel driver chip 200 on the base 1 and the orthographic projections of the plurality of signal channel terminals 201 of the pixel driver chip 200 on the base 1 at least partially overlap with an orthographic projection of the second ground sub-line GND2 on the base 1, respectively. In this way, the pitch (i.e. the periodical size) of the repetitive units in the first direction X may be further reduced, thereby contributing to the realization of the high-resolution display panel.

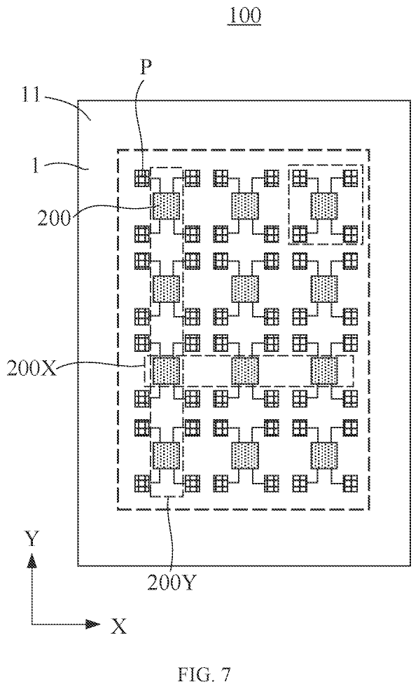

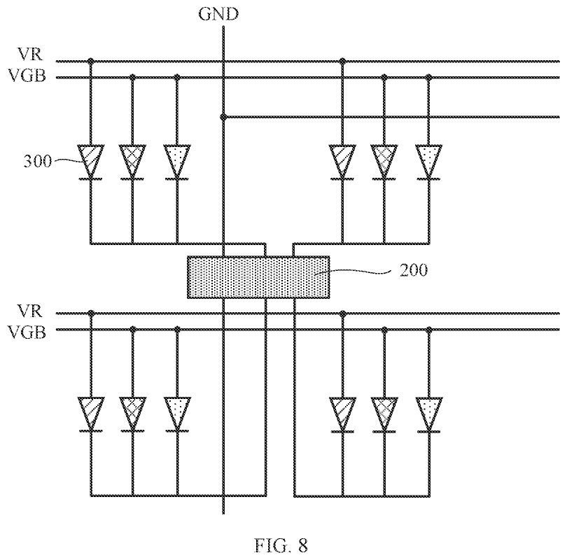

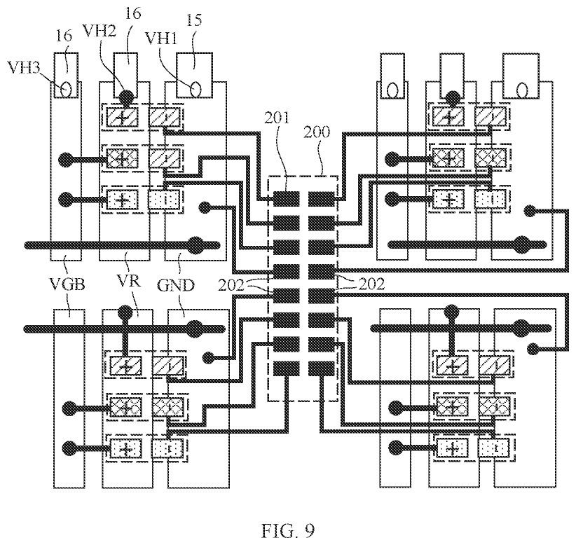

FIG. 7 is a schematic top view of a front surface of a display panel according to some other exemplary embodiments of the present disclosure. FIG. 8 is a diagram showing a principle of driving a pixel of the display panel shown in FIG. 7. FIG. 9 is a schematic diagram of a structure of a pixel of the display panel shown in FIG. 7. It will be noted that the followings mainly describes the differences between the embodiment shown in FIG. 7 to FIG. 9 and the embodiments described above, and for some other details in this embodiment, reference may be made to the foregoing descriptions, which will not be repeated here.

In the embodiments shown in FIG. 7 to FIG. 9, one pixel driver chip 200 is used to drive a plurality of pixel units P, that is, one pixel driver chip 200 corresponds to a plurality of pixel units P. For example, one pixel driver chip 200 is used to drive four pixel units P, that is, one pixel driver chip 200 corresponds to four pixel units P.

In some exemplary embodiments, the plurality of pixel units driven by a same pixel driver chip 200 include pixel units P located in two rows adjacent to each other and/or pixel units P located in two columns adjacent to each other.

In the embodiments of the present disclosure, for case of description, signal terminals of the pixel driver chip 200 connected to the same pixel unit P are divided into a group, that is, the pixel driver chip 200 may include a plurality of signal terminal groups.

In the case that the pixel unit P includes three sub-pixels, the pixel driver chip 200 includes twelve signal channel terminals 201 and four ground signal terminals 202. In this case, the pixel driver chip 200 may include four signal terminal groups, and cach signal terminal group may include three signal channel terminals 201 and one ground signal terminal 202. The three signal channel terminals 201 in the signal terminal group are electrically connected to the first electrodes 301 of the plurality of light-emitting diodes of one pixel unit in a one-to-one correspondence. The plurality of ground signal terminals 202 of the plurality of signal terminal groups in a same pixel driver chip 200 are electrically connected to a plurality of ground lines GND through wired connection, respectively.

It will be noted that in FIG. 9, four pixel units located in different rows and pixel driver chips corresponding to the four pixel units are schematically shown, where the four pixel units may be four pixel units in the top two rows in the display panel.

With reference to FIG. 9, for a same pixel driver chip 200, orthographic projections of ground signal terminals 202 and signal channel terminals 201 in at least two signal terminal groups for driving the pixel units in a same column on the base 1 are arranged in a column along the second direction Y.

For a same pixel driver chip 200, orthographic projections of the ground signal terminals 202 and signal channel terminals 201 in at least two signal terminal groups for driving the pixel units in different columns on the base 1 are arranged in different columns, that is, they are arranged at intervals along the first direction X.

The plurality of pixel driver chips 200 include at least one chip column. The chip column is parallel to the pixel columns in the pixel array, and is located between two pixel columns adjacent to each other.

In this embodiment, more than one pixel unit P is connected to the same pixel driver chip 200, thereby reducing the number of signal wires on the base, so that the process difficulty may be reduced, and the power consumption and costs of the driving of the entire display module may also be reduced.

In the embodiments of the present disclosure, more than one pixel unit connected to the same pixel driver chip 200 may be referred to as a pixel unit group. One pixel unit group includes more than one pixel unit P. The pixel array may include one pixel unit group. Alternatively, the pixel array may include a plurality of pixel unit groups. That is, the plurality of pixel units P in the pixel array may be divided into a plurality of pixel unit groups. At least one pixel unit group in the plurality of pixel unit groups includes more than one pixel unit P. The pixel array including a plurality of pixel unit groups is taken as an example, and each of the plurality of pixel unit groups may include the same number of pixel units P. Alternatively, the numbers of pixel units P in two pixel unit groups may be different.

More than one of the pixel units P in the pixel unit group may be arranged in different pixel rows PX in the pixel array. That is, at least two of the pixel units P in the pixel unit group may be arranged in different pixel rows PX in the pixel array. The different pixel rows PX may be sequentially arranged pixel rows PX. However, the embodiments of the present disclosure do not impose special limitations on this. Taking the pixel unit group including four pixel units P as an example, two pixel units P of the four pixel units P are arranged in different pixel rows PX. One of the two pixel units P is arranged in an nth pixel row PX, and the other one of the two pixel units Pis arranged in an (n+1) th pixel row PX, where n is an integer greater than or equal to 1. The nth pixel row PX and the (n+1)^{th} pixel row PX are sequentially arranged pixel rows PX. Alternatively, three pixel units P of the four pixel units P may be arranged in different pixel rows PX. One of the three pixel units P is arranged in the nth pixel row PX, another one of the three pixel units P is arranged in the (n+1)^{th} pixel row PX, and the remaining one of the three pixel units P is arranged in an (n+2) th pixel row PX.

Further, as shown in FIG. 9, more than one of the pixel units P of the pixel unit group may be arranged in different pixel columns PY in the pixel array. That is, at least two of the pixel units P of the pixel unit group are arranged in different pixel columns PY in the pixel array.

The different pixel columns PY may be sequentially arranged pixel columns PY. However, the embodiments of the present disclosure do not impose special limitations on this. Taking the pixel unit group including four pixel units P as an example, two pixel units P of the four pixel units P are arranged in different pixel columns PY. One of the two pixel units P is arranged in an mth pixel column PY, and the other one of the two pixel units P is arranged in an (m+1)^{th} pixel column PY, where m is an integer greater than or equal to 1. The mth pixel column PY and the (m+1)^{th} pixel column PY are sequentially arranged pixel columns PY. Alternatively, three pixel units P of the four pixel units P may be arranged in different pixel columns PY. One of the three pixel units P is arranged in the mth pixel column PY, another one of the three pixel units P is arranged in the (m+1)^{th} pixel column PY, and the remaining one of the three pixel units P is arranged in an (m+2)^{th} pixel column PY.

It will be noted that in the embodiments of the present disclosure, the pixel driver chip 200 is a separate element which may be assembled to the base 1 by using the surface mounting technology. The base 1 is provided with pads, and in the process of assembling the pixel driver chip 200 onto the base 1 by using the surface mounting technology, the signal terminals of the pixel driver chip 200 are fixedly connected to the pads.

There are a plurality of pixel driver chips 200, and the plurality of pixel driver chips 200 jointly drive the pixel array to display. As shown in FIG. 3 and FIG. 7, one pixel unit P is connected to one pixel driver chip 200, or the pixel units P of the pixel unit group are connected to a same pixel driver chip 200. Taking the pixel unit group including four pixel units P and each pixel unit P including three sub-pixels as an example, the three sub-pixels in each of the four pixel units P are all connected to a same pixel driver chip 200, that is, the pixel driver chip 200 is connected to twelve sub-pixels. The pixel driver chip 200 may include twelve signal channel terminals 201, and the twelve signal channel terminals 201 are connected to the first electrodes of the light-emitting diodes of the respective sub-pixels in a one-to-one correspondence. Taking the pixel array including a plurality of pixel unit groups mentioned above as an example, the plurality of pixel driver chips 200 may be used to drive the plurality of pixel unit groups for display in one-to-one correspondence.

As shown in FIG. 3 and FIG. 7, the plurality of pixel driver chips 200 may be arranged in an array, so as to form a plurality of chip columns 200Y and a plurality of chip rows 200X. The chip row 200X may be parallel to the pixel row PX mentioned above. The chip column 200Y may be parallel to the pixel column PY mentioned above. The number of pixel driver chips 200 in the chip column 200Y may be less than or equal to the number of pixel units P in the pixel column PY. At least one chip column 200Y in the plurality of chip columns 200Y is arranged between two columns of pixels PY adjacent to each other, and the chip column 200Y between the two columns of pixels PY adjacent to each other is used to drive the two columns of pixels PY adjacent to each other for display. Only one chip column 200Y is provided between the two columns of pixels PY adjacent to each other. The two columns of pixels PY adjacent to each other may form more than one pixel unit group, the number of the pixel units P included in each pixel unit group may be the same or different, and the plurality of pixel unit groups are distributed in a direction in which the pixel column PY extends. Taking each pixel column PY including six rows of pixel units P and each pixel unit group including four pixel units P, for the two columns of pixels PY adjacent to each other, two pixel units P in a first row and two pixel units P in a second row may constitute one pixel unit group, two pixel units P in a third row and two pixel units P in a fourth row may constitute another pixel unit group, and two pixel units P in a fifth row and two pixel units Pin a sixth row may constitute yet another pixel unit group. In addition, the pixel driver chips 200 in the chip column 200Y between the two columns of pixels PY adjacent to each other are connected to the pixel unit groups in a one-to-one correspondence.

Alternatively, the plurality of pixel driver chips 200 may not be arranged in an array. As long as one pixel driver chip 200 is connected to more than one pixel unit P in the pixel unit group, the number of the signal wires on the base may be reduced. In an embodiment, a plurality of pixel driver chips 200 form a plurality of chip rows 200X, but they do not form a chip column 200Y, and the number of pixel driver chips 200 in each chip row 200X may be equal. In another embodiment, a plurality of pixel driver chips 200 form a plurality of chip columns 200Y, but they do not form a chip row 200X, and the number of pixel driver chips 200 in each chip column 200Y may be equal.

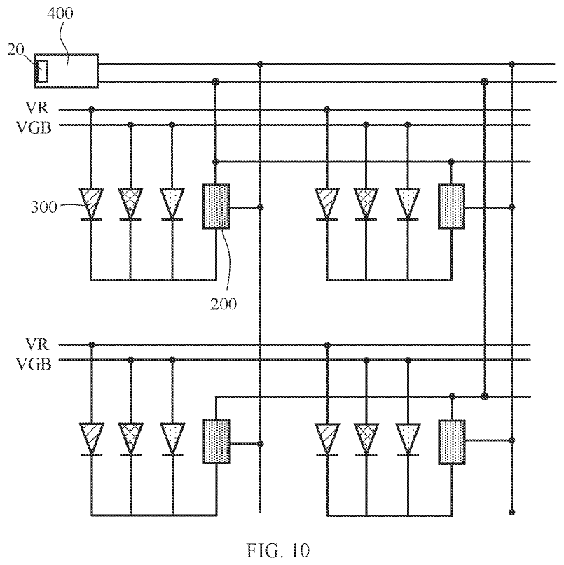

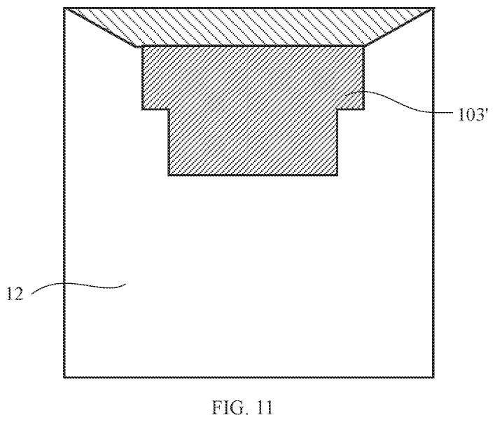

FIG. 10 is a diagram showing a principle of driving a pixel of a display panel according to some other exemplary embodiments of the present disclosure. FIG. 11 is a schematic top view of a back surface of the display panel shown in FIG. 10. It will be noted that the followings mainly describes the differences between the embodiments shown in FIG. 10 to FIG. 11 and the embodiments described above, and for some other details in this embodiment, reference may be made to the foregoing descriptions, which will not be repeated here.

In some exemplary embodiments of the present disclosure, the signal processing chip may be a general control chip 400. In these embodiments, the display panel 100 includes: the pixel driver chips 200 on the first surface of the base for driving the pixel units, and the general control chip 400. The general control chip 400 includes a wireless signal receiving terminal 20. The wireless signal receiving terminal 20 is configured to receive at least one signal wirelessly. For example, the at least one signal includes a data signal. Alternatively, the at least one signal includes a data signal and a power supply voltage signal. The general control chip 400 is in wired connection with the pixel driver chip 200 to perform signal transmission with the pixel driver chip 200.

In the embodiments of the present disclosure, data signals and power supply voltage signals are received wirelessly through the wireless signal receiving terminal of the general control chip, so that it is possible to reduce the bonding points and the wires on the side surface of data signal lines and power supply voltage signal lines, thereby facilitating a further reduction of the process difficulty, thereby improving the product yield.

In the embodiments of the present disclosure, as shown in FIG. 11, two or more power supply circuit boards 103 may be integrated as one circuit board 103′, so as to increase process reliability and reduce costs.

In the embodiments of the present disclosure, the number of general control chips 400 may be one or more. Specifically, a plurality of general control chips 400 may be provided. The general control chip 400 is in wired connection with the plurality of pixel driver chips 200 to perform signal transmission with the pixel driver chips. For example, the plurality of general control chips 400 may be provided at four corners of the display panel 100, or may be provided at intervals in the peripheral area of the display panel 100. By providing a plurality of general control chips, the design of the wiring on the display panel may be simplified, thereby avoiding the problem of unstable or uneven output caused by providing only one chip.

It will be noted that in the embodiments of the present disclosure, the first power supply signal line VR, the second power supply signal line VGB, the ground line GND and other signal lines may be directly formed on the base 1. For example, they may be manufactured by using processes such as film forming and patterning. After the signal lines are formed by using processes such as film forming and patterning, the pixel driver chip 200 may be assembled to the base 1. An orthographic projection of the pixel driver chip 200 on base I overlaps with an orthographic projection of part of the signal lines on the base 1, so that a space for wiring may be maximized and utilized reasonably, and the distribution density of the pixels may be increased.

Some exemplary embodiments of the present disclosure also provide a display device. The display device includes a display panel as described above. This display device may be used for any product or component with display function. For example, the display device may be a smart phone, a portable phone, a navigation device, a television (TV), a car audio body, a laptop, a tablet, a portable multimedia player (PMP), a personal digital assistant (PDA), etc., and display products in the fields of outdoor large screen display, central control display, etc.

It will be understood that the display device of some exemplary embodiments of the present disclosure has all the characteristics and advantages of the above display panel. These characteristics and advantages may be referred to the description of the display panel mentioned above, which will not be repeated here.

Although some embodiments of the entire inventive concept of the present disclosure have been illustrated and explained, those of ordinary skill in the art will understand that changes may be made to these embodiments without departing from the principles and spirit of the entire inventive concept of the present disclosure, and the scope of the present disclosure is limited by the claims and their equivalents.

1. A display panel, comprising:
a base comprising a first surface and a second surface located on opposite sides of the base respectively;
a pixel array provided on the first surface of the base, wherein the pixel array comprises a plurality of pixel units arranged in an array along a first direction and a second direction, at least one pixel unit comprises a plurality of light-emitting diodes, and the light-emitting diodes each comprise a first electrode and a second electrode; and
a signal processing chip provided on the first surface of the base, wherein the signal processing chip comprises at least one signal channel terminal electrically connected to the first electrode of at least one of the light-emitting diodes.
wherein the signal processing chip further comprises one or more wireless signal receiving terminals, the one or more wireless signal receiving terminals being configured to receive at least one signal wirelessly, and the at least one signal comprises a data signal.

2. The display panel of claim 1, wherein the at least one signal further comprises a power supply voltage signal.

3. The display panel of claim 1, wherein the signal processing chip is a pixel driver chip for driving a pixel unit.

4. The display panel of claim 3, wherein a plurality of signal processing chips are provided on the first surface of the base, each signal processing chip is configured to drive a respective one pixel unit, and the each signal processing chip comprises a plurality of signal channel terminals electrically connected to first electrodes of a plurality of light-emitting diodes of the respective one pixel unit in a one-to-one correspondence.

5. The display panel of claim 4, further comprising a ground line provided on the first surface of the base, the ground line being configured to transmit a ground signal,
wherein each signal processing chip further comprises a ground signal terminal, the ground signal terminal being electrically connected to the ground line through wired connection.

6. The display panel of claim 5, wherein in the each signal processing chip for driving a respective one pixel unit, an orthographic projection of the ground signal terminal on the base and orthographic projections of the plurality of signal channel terminals on the base are arranged in a column along the second direction.

7. The display panel of claim 5, further comprising a circuit board and a ground signal lead, wherein the circuit board is provided on the second surface of the base, at least a part of the ground signal lead is provided on a first side surface of the base, and the first side surface is a side surface of the base between the first surface and the second surface; and
the circuit board is electrically connected to the ground line through the ground signal lead.

8. The display panel of claim 7, further comprising a plurality of power supply signal lines provided on the first surface of the base, wherein second electrodes of the plurality of light-emitting diodes of the respective one pixel unit are electrically connected to the plurality of power supply signal lines, respectively.

9. The display panel of claim 8, further comprising a power supply signal lead, wherein at least a part of the power supply signal lead is provided on the first side surface of the base; and
the circuit board is electrically connected to the power supply signal line through the power supply signal lead.

10. The display panel of claim 5, wherein the ground line comprises a first ground sub-line extending in the first direction and a second ground sub-line extending in the second direction, and the first ground sub-line and the second ground sub-line intersect with each other to form a mesh.

11. The display panel of claim 10, wherein each of an orthographic projection of the ground signal terminal on the base and orthographic projections of the plurality of signal channel terminals on the base at least partially overlaps with an orthographic projection of the second ground sub-line on the base, respectively.

12. The display panel of claim 3, wherein:
the signal processing chip is configured to drive more than one pixel unit, the signal processing chip comprises a plurality of signal terminal groups, and each signal terminal group comprises more than one signal channel terminal; and
the more than one signal channel terminal of each signal terminal group of the signal processing chip are is electrically connected to first electrodes of a plurality of light-emitting diodes of one pixel unit in a one-to-one correspondence.

13. The display panel of claim 12, wherein the more than one pixel unit driven by the signal processing chip comprises pixel units located in two rows adjacent to each other, and/or, pixel units located in two columns adjacent to each other.

14. The display panel of claim 12, further comprising a ground line provided on the first surface of the base, wherein the ground line is configured to transmit a ground signal; and
wherein each signal terminal group further comprises a ground signal terminal, and a plurality of ground signal terminals of the plurality of signal terminal groups of the signal processing chip are electrically connected to a plurality of ground lines through wired connection.

15. The display panel of claim 12, wherein a plurality of signal processing chips are provided on the first surface of the base, arranged in at least one chip column parallel to a pixel column in the pixel array, and the chip column is between two pixel columns adjacent to each other.

16. The display panel of claim 15, wherein for a same one of the signal processing chips, orthographic projections of ground signal terminals and signal channel terminals in at least two signal terminal groups for driving pixel units in a same column on the base are arranged in a column along the second direction.

17. The display panel of claim 16, wherein for a same one of the signal processing chips, orthographic projections of ground signal terminals and signal channel terminals in at least two signal terminal groups for driving pixel units in different columns on the base are arranged in different columns.

18. The display panel of claim 1, wherein:
the signal processing chip is a general control chip; and
the display panel further comprises one of more pixel driver chips for driving the pixel units on the first surface of the base, and the general control chip is in wired connection with the one or more pixel driver chip chips to perform signal transmission with the one or more pixel driver chips.

19. The display panel of claim 18, wherein a plurality of general control chips and pixel driver chips are provided, each of the general control chips being in wired connection with a plurality of the pixel driver chips to perform signal transmission with the plurality of the pixel driver chips.

20. A display device comprising the display panel of claim 1.
